(19) United States
(12) Patent Application Publication
(10) Pub. No.: US 2019/0309408 A1
(43) Pub. Date: Oct. 10, 2019

(54) VACUUM DEVICE AND METHOD FOR COATING COMPONENTS OF A VACUUM DEVICE

(71) Applicants: PFEIFFER VACUUM COMPONENTS & SOLUTIONS GMBH, Goeltingen (DE); MOVATEC GMBH, Kempten (DE)

(72) Inventors: Thorsten LAUER, Hohenkammer (DE); Andreas KRAFT, Höhn-Oellingen (DE)

(73) Assignees: Pfeiffer Vacuum Components & Solutions GmbH, Goeltingen (DE); Movatec GmbH, Kempten (DE)

(21) Appl. No.: 16/306,733

(22) PCT Filed: Jun. 1, 2017
(86) PCT No.: PCT/EP2017/063343

§ 371 Date: Dec. 3, 2018

(30) Foreign Application Priority Data
Jun. 3, 2016 (DE) 102016110357.8
Nov. 30, 2016 (DE) 102016123146.0

(51) Int. Cl. C23C 14/14; C23C 14/35; C23C 14/34; F04B 37/04; F04B 37/14

(52) U.S. Cl. CPC C23C 14/14; C23C 14/35; F04D 19/042; F04B 37/04; F04B 37/14; C23C 14/3407

(57) ABSTRACT

A vacuum device comprising at least one component having a portion which, during operation of the vacuum device, is in contact with a vacuum and which is coated at least in part by a layer which absorbs gas particles, in particular with a layer of a no-evaporable getter (NEG) material.

The invention relates to a vacuum device that is provided at least in part with a film absorbing gas particles, in particular with a film of an NEG material (NEG=non-evaporable getter). The invention additionally relates to the use of a component coated at least sectionally with a film absorbing gas particles in a vacuum device. The film can in particular be a film of a NEG material. The invention further relates to methods of NEG coating of vacuum devices and/or of components of vacuum devices. The invention furthermore relates to a method of operating a vacuum device.

The vacuum device can, for example, be a vacuum pump, in particular a turbomolecular vacuum pump, a mass spectrometer or another measuring device suitable for vacuum technology, a sensor, or a valve that can be used in the field of vacuum technology.

Films or coatings that are able to absorb gas particles are generally known. NEG coatings and wire coating processes for manufacturing such coatings are in particular generally known.

Reference is generally made with respect to the prior art to DE 697 19 507 T2. DE 698 17 775 T2, DE 600 00 873 T2, and WO 2003/074753 A1.

Despite the known capability of such films or coatings to absorb gas particles, vacuum devices and here in particular mechanical vacuum pumps providing a generation of a vacuum have to date not themselves been provided with such films or coatings.

It is the object of the invention to improve vacuum devices, in particular with respect to their performance and to provide improved methods of manufacturing gas-absorbing films or coatings.

This object is satisfied by the respective features of the independent claims.

In accordance with the invention, the vacuum device that is in particular a vacuum pump (e.g. a turbomolecular pump), a sensor (e.g. a vacuum sensor), a measuring device (e.g. a mass spectrometer), or a valve comprises at least one component that has a section that is in contact with a vacuum in an operation of the vacuum device and that is coated at least sectionally with a film absorbing gas particles (e.g. atoms, molecules, ions), in particular with a film of a non-evaporable getter (NEG) material.

Two advantageous effects are achieved by the film. On the one hand, the coating reduces or prevents the degassing of the coated component (passive effect of the film). On the other hand, a pump effect can be provided in an activated state of the material of the film by its gas absorption (active effect of the film), i.e. the film not only contributes to the maintenance of the vacuum, but it also even reduces the pressure present by the absorption of gas particles. Particularly with devices that are used in the ultra-high vacuum (UHV) range, the above-described dual effect of the film is of great advantage.

A coating of the surfaces over as large an area as possible of the device that are in contact with the vacuum is generally desirable. In many cases—also above all against the background of the manufacturing costs associated therewith—it is, however, sufficient to only coat specific components of the surface sections. The film can comprise titanium, zirconium and/or vanadium. It in particular substantially only comprises titanium, zirconium and/or vanadium. On a mixture of titanium, zirconium, and vanadium, titanium and vanadium can be provided in approximately the same proportions. In accordance with an advantageous embodiment, the film includes less zirconium than titanium and/or vanadium. For example, titanium, zirconium, and vanadium are present in a mixing ratio of approximately 34:32:34. In general, however, NEG materials are also known and can be used in accordance with the invention that comprise said elements in different mixing ratios and/or comprise different elements or substances.

Different substances or substance mixtures can, however, also be used for forming the film absorbing gas particles for specific fields of application.

The component can be a component that is static in operation of the device. It is in particular a housing and/or a component fixedly connected to a housing. For example, the inner surface of the housing or of individual housing parts is partly or substantially completely coated with NEG material. In a turbomolecular pump, stator disks and stator spacer rings can also be correspondingly coated.

The component can also be a component that can be driven to make a movement in operation of the device; in a turbomolecular pump, for example, a component such as a rotor disk generating a pump effect.

As has already been initially mentioned, the device can be a vacuum pump, in particular a turbomolecular pump. In this case, it is particularly effective if an inlet region of the pump and/or components arranged in the inlet region of the pump is/are at least sectionally coated with the layer. It is generally also conceivable to coat components sectionally or completely that are connected upstream of a direct inlet region of the pump. The same also applies analogously to other vacuum devices.

The invention further relates to the use of a component in a vacuum device, said component being coated at least sectionally with a film absorbing gas particles, in particular with a film of a non-evaporable getter (NEG) material.

In a first method in accordance with the invention, the NEG coating of components of a vacuum plant and/or of components of vacuum devices takes place by a sputtering process, in particular by magnetron sputtering, with at least one non-wire shaped target being used.

In a second method in accordance with the invention, the NEG coating of components of a vacuum plant and/or of components of vacuum devices takes place by a sputtering process, in particular by magnetron sputtering, with the target and the component being moved relative to one another during the sputtering process. The relative movement can take place such that either the target is: still and the component is moved or such that the component is still and the target is moved.

These two methods in accordance with the invention—and also their embodiments and further developments—can generally be combined with one another as desired.

The general, known properties of NEG coatings and the technique of sputtering and in particular of magnetron sputtering do not need to be looked at in more detail since they are generally known to the skilled person and form part of general technical knowledge.

A special feature of the first aspect of the invention comprises no wire coating process being used, but the target of the sputtering device rather being configured or formed directly in dependence on the respective component to be coated or on a surface of the respective component to be coated. This will be looked at in more detail in the following.

A special feature of the second aspect of the invention comprises no static sputtering process being carried out, but the target of the sputtering device and the respective component (substrate) to be coated being moved relative to one another during the sputtering process. The target and the component to be coated can have any desired shapes here. It has been found that the coating process can be dramatically accelerated by the relative movement between the substrate and the target. For example, in the coating of a pipe having a length of 1 m with an NEG coating having a thickness of 1 μm, the required time duration for the coating process was able to be reduced from approximately 2 to 3 days with a wire coating process to approximately 10 to 12 hours with the method in accordance with the invention.

In accordance with an embodiment of the two methods in accordance with the invention, a target can be used that has an at least sectionally planar target surface, in particular a completely planar target surface (called a planar target in the following). A tubular component can in particular be NEG coated by means of such a planar target. The planar target is preferably oriented relative to the tubular component during the sputtering process such that the outer margin of the target is disposed in a plane extending perpendicular to the longitudinal axis of the tubular component. The diameter of the planar target can be correspondingly scaled in dependence on the inner diameter of the component.

In another embodiment, a planar target can be use that is arranged as movable to provide plate-like components or components having planar sections comparatively quickly with NEG coatings.

A vacuum device in accordance with the invention can be composed of a plurality of components coated in accordance with the invention. For example, vacuum vessels such as vacuum chambers can be put together from plate-like or tubular components coated in accordance with the invention. This also applies to components of a vacuum plant such as pipes.

Provision is preferably made that the target comprises an alloy or consists of an alloy that includes titanium, zirconium and vanadium. In a possible composition of this alloy, its components are contained at least approximately in equal portions. In a particularly preferred embodiment, the alloy contains titanium, zirconium, and vanadium in a ratio of 34:32:34.

Provision is furthermore preferably made that a NEG coating is generated that contains titanium, zirconium, and vanadium in a ratio of 34:32:34.

It has been found that a NEG coating manufactured in accordance with the invention can be activated by heating and, in an activated state, is able to bind residual gas atoms at its surface.

It has furthermore been found that in accordance with the invention a NEG coating can be manufactured that is able, after a repeat activation, to desorb residual gas atoms previously bound to its surface and/or to allow them to migrate into the interior of the NEG coating. The greater portion of the residual gas atoms is in particular desorbed and only a small portion of the residual gas atoms migrates into the interior of the coating. The desorbed portion can be completely pumped out on a repeat activation by additional (mechanical) pumps and can be removed from the vacuum volume.

It has further been found that in accordance with the invention a NEG coating can be manufactured that has a degassing rate in a non-activated state that amounts to between 10⁻¹⁴ and 10⁻¹⁵ mbar*l*s⁻¹*cm⁻².

It has further been found that in accordance with the invention a NEG coating can be manufactured by means of which a pressure of less than 5×10⁻¹¹ can be reached in a closed space without an additional pump effect, that is without making use of an additional pump device.

Provision can furthermore be made in accordance with the invention that the sputtering process is carried out such that foreign atoms present on a surface of the respective component to be coated are removed by the sputtering atoms.

In the method in accordance with the invention of operating a vacuum device, in particular a vacuum device disclosed here, provision is made that at least the component provided with the NEG coating is activated by heating before the use in accordance with the invention of the vacuum device.

Provision can be made here that the component is heated to approximately or to exactly 200° C. Temperatures above or below this temperature value are likewise possible. It has in particular been found that a pump effect of the surface occurs on an activation of the component at approximately or at exactly 200° C. so that pressures of less than 5×10⁻¹¹ can be reached. It has in particular also been found, however, that a pump effect of the surface occurs on a partial activation of the component at approximately or at exactly 80° C. so that pressures of less than 5×10⁻⁹ can be reached.

Provision can furthermore be made that the component is kept at a temperature that amounts to approximately or to exactly 200° C. over a time period of at least substantially 24 hours, with temperatures above or below this temperature value likewise being possible.

It has been found that subsequent to an operating phase of a vacuum device with a previously activated coating, the residua gas atoms bound to the surface of the NEG coating during operation desorb and/or migrate into the interior of the NEG coating when the NEG coating is again activated after the respective operating phase. The NEG coating or the respective component consequently does not become unusable after a single use. The readiness for use of the vacuum device can rather be restored via additional measures going beyond a repeat activation.

The invention will be described in the following by way of example with reference to advantageous embodiments and to the enclosed Figures. There are shown, schematically in each case:

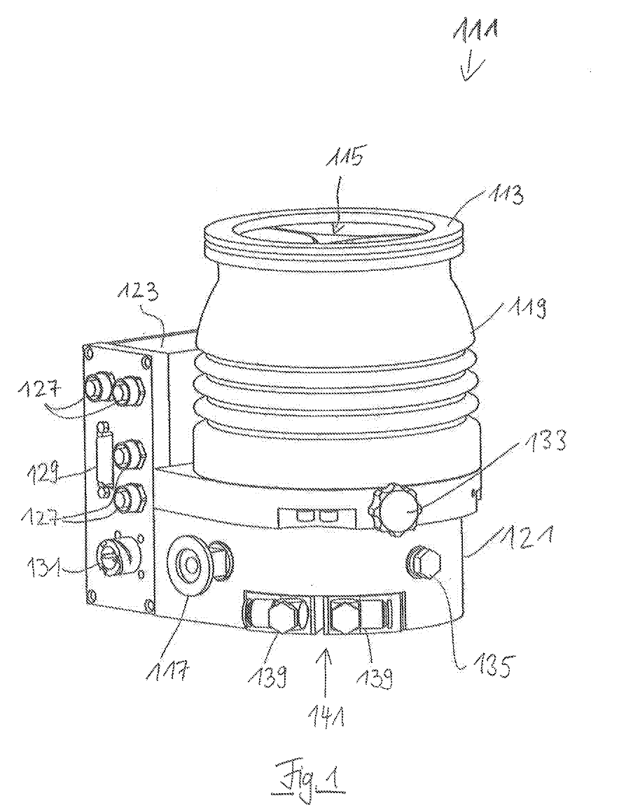

FIG. 1 a perspective view of a turbomolecular pump;

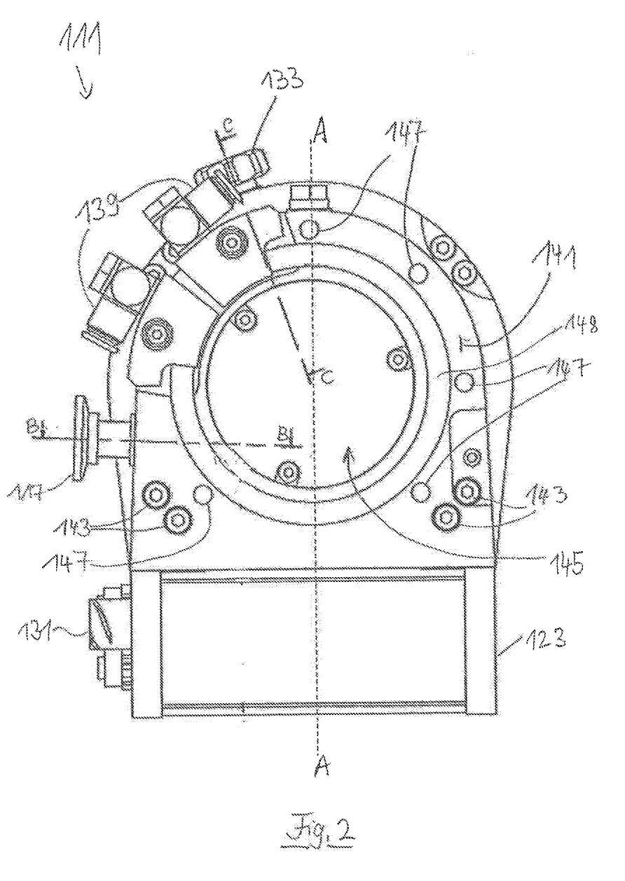

FIG. 2 a view of the lower side of the turbomolecular pump of FIG. 1;

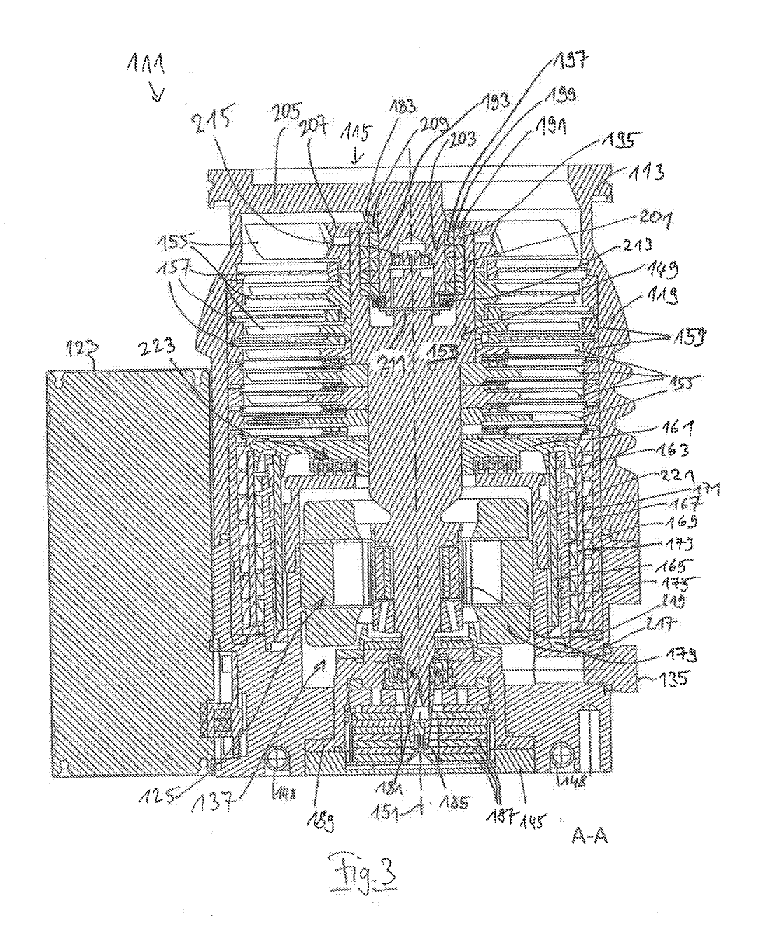

FIG. 3 a cross-section of the turbomolecular pump along the line A-A shown in FIG. 2;

FIG. 4 a cross-sectional view of the turbomolecular pump along the line B-B shown in FIG. 2;

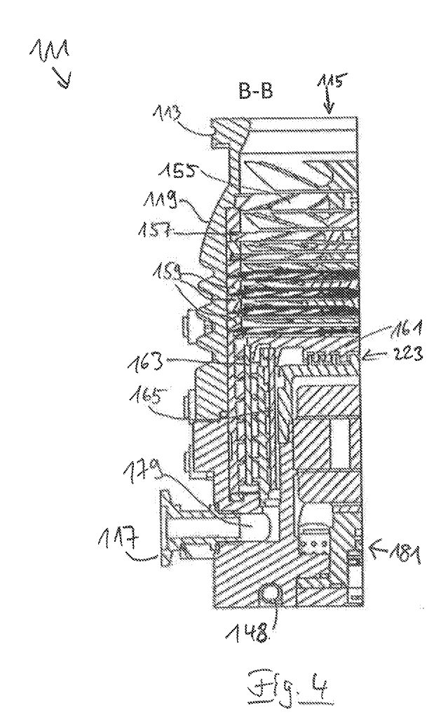

FIG. 5 a cross-sectional view of the turbomolecular pump along the line C-C shown in FIG. 2;

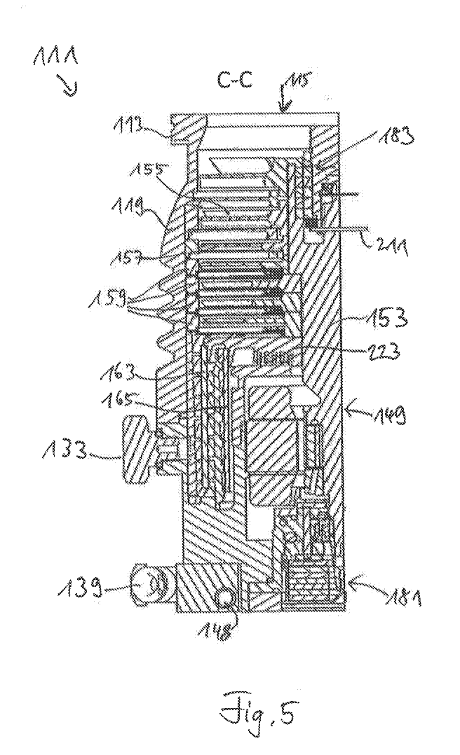

FIG. 6 a perspective view of a magnetron sputtering head for a NEG coating of components, in particular tubular components;

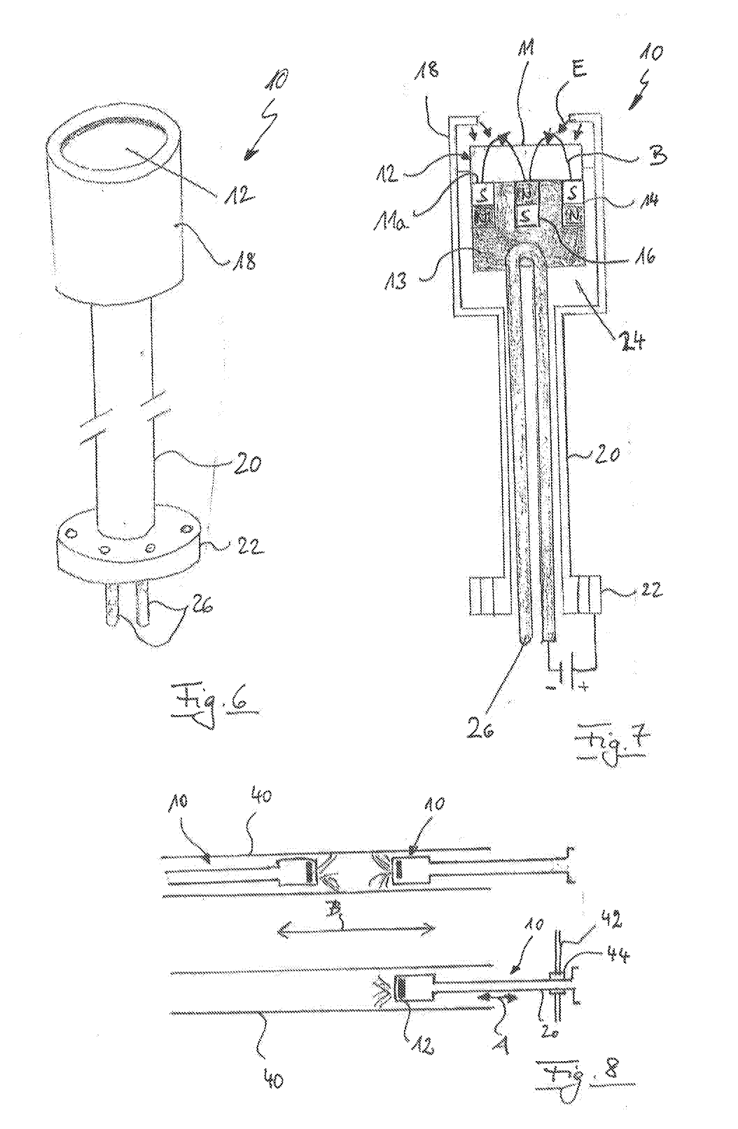

FIG. 7 a cross-section of the magnetron sputtering head shown in FIG. 6; and

FIG. 8 a schematic diagram of the design of a plant for a NEG coating of tubular components with one sputtering head (bottom) and with two sputtering heads (top).

The turbomolecular pump 111 shown in FIG. 1 comprises a pump inlet 115 which is surrounded by an inlet flange 113 and to which a recipient, not shown, can be connected in a manner known per se. The gas from the recipient can be sucked out of the recipient via the pump inlet 115 and can be conveyed through the pump to a pump outlet 117 to which a backing pump such as a rotary vane pump can be connected.

The inlet flange 113 forms the upper end of the housing 119 of the vacuum pump 111 on the alignment of the vacuum pump in accordance with FIG. 1. The housing 119 comprises a lower part 121 at which an electronics housing 123 is laterally arranged. Electrical and/or electronic components of the vacuum pump 111 are accommodated in the electronics housing 123, e.g. to operate an electric motor 125 arranged in the vacuum pump. A plurality of connectors 127 for accessories are provided at the electronics housing 123. In addition, a data interface 129, e.g. in accordance with the RS485 standard, and a power supply connector 131, are arranged at the electronics housing 123.

A flood inlet 133, in particular in the form of a flood valve, via which the vacuum pump 111 can be flooded, is provided at the housing 119 of the turbomolecular pump 111. In the region of the lower part 121, a barrier gas connector 135 is furthermore arranged which is also called a purge gas connector and via which purge gas can be supplied to the motor space 137 in which the electric motor 125 is accommodated in the vacuum pump 111 to protect the electric motor 125 from the gas conveyed by the pump (see e.g. FIG. 3). Two coolant connectors 139 are furthermore arranged in the lower part 121, with one of the coolant connectors being provided as an inlet and the other coolant connector being provided as an outlet for coolant that can be conducted into the vacuum pump for cooling purposes.

The lower side 141 of the vacuum pump can serve as a standing surface so that the vacuum pump 111 can be operated in a standing position on the lower side 141. The vacuum pump 111 can, however, also be fastened to a recipient via the inlet flange 113 and can thus so-to-say be operated in a suspended manner. In addition, the vacuum pump 111 can be designed such that it can also be put into operation when it is aligned in a different manner to that shown in FIG. 1. Embodiments of the vacuum pump can also be implemented in which the lower side 141 can be arranged not directed downwardly, but rather facing to the side or directed upwardly.

Various screws 143 by means of which components of the vacuum pump that are not further specified here are fastened to one another are arranged at the lower side 141 that is shown in FIG. 2. A bearing cap 145 is, for example, fastened to the lower side 141.

In addition, fastening bores 147 via which the pump 111 can, for example, be fastened to a support surface are arranged at the lower side 141.

A coolant line 148 is shown in FIGS. 2 to 5 in which the coolant led in and out via the coolant connectors 139 can circulate.

As the cross-sectional views of FIGS. 3 to 5 show, the vacuum pump comprises a plurality of process gas pumps for conveying the process gas present at the pump inlet 115 to the pump outlet 117.

A rotor 149 is arranged in the housing 119 and has a rotor shaft 153 rotatable about a rotation axis 151.

The turbomolecular pump 111 comprises a plurality of turbomolecular pump stages connected to one another in series in a pump-active manner and having a plurality of radial rotor disks 155 fastened to the rotor shaft 153 and a plurality of stator disks 157 arranged between the rotor disks 155 and fixed in the housing 119. A rotor disk 155 and an adjacent stator disk 157 each form one turbomolecular pump stage here. The stator disks 157 are held by spacer rings 159 at a desired axial spacing from one another.

The vacuum pump additionally comprises Holweck pump stages arranged in one another in a radial direction and connected to one another in series in a pump-active manner. The rotor of the Holweck pump stages comprises a rotor hub 161 arranged at the rotor shaft 153 and two Holweck rotor sleeves 163, 165 which are fastened to the rotor hub 161, which are supported by it, which are of cylinder jacket shape, which are orientated coaxially to the axis of rotation 151 and which are nested in one another in the radial direction. Furthermore, two Holweck stator sleeves 167, 169 are provided which are of cylinder jacket shape, which are likewise orientated coaxially to the axis of rotation 151 and which are nested in one another in the radial direction.

The pump-active surfaces of the Holweck pump stages are formed by the jacket surfaces, that is by the radial inner surfaces and/or outer surfaces, of the Holweck rotor sleeves 163, 165 and of the Holweck stator sleeves 167, 169. The radial inner surface of the outer Holweck stator sleeve 167 is disposed opposite the radial outer surface of the outer Holweck rotor sleeve 163 while forming a radial Holweck gap 171 and forms the first Holweck pump stage following the turbomolecular pumps with it. The radial inner surface of the outer Holweck rotor sleeve 163 is disposed opposite the radial outer surface of the inner Holweck stator sleeve 169 while forming a radial Holweck gap 173 and forms a second Holweck pump stage with it. The radial inner surface of the inner Holweck stator sleeve 169 is disposed opposite the radial outer surface of the inner Holweck rotor sleeve 165 while forming a radial Holweck gap 175 and forms the third Holweck pump stage with it.

A radially extending passage can be provided at the lower end of the Holweck rotor sleeve 163 and the radially outwardly disposed Holweck gap 171 is connected via it to the middle Holweck gap 173. In addition, a radially extending passage via which the middle Holweck gap 173 is connected to the radially inwardly disposed Holweck gap 175 can be provided at the upper end of the inner Holweck stator sleeve 169. The Holweck pump stages nested in one another are thereby connected to one another in series. A connection passage 179 to the outlet 117 can furthermore be provided at the lower end of the radially inwardly disposed Holweck rotor sleeve 165.

The above-named pump-active surfaces of the Holweck stator sleeves 163, 165 each have a plurality of Holweck grooves extending in the axial direction spirally about the axis of rotation 151 while the oppositely disposed jacket surfaces of the Holweck rotor sleeves 163, 165 are smooth and drive the gas for operating the vacuum pump 111 into the Holweck grooves.

A roller element bearing 181 is provided in the region of the pump outlet 117 and a permanent magnet bearing 183 is provided in the region of the pump inlet 115 for the rotatable support of the rotor shaft 153.

In the region of the roller element bearing 181, a conical splash nut 185 is provided which has an outer diameter increasing toward the roller element bearing 181. The splash nut 185 is in sliding contact with at least one wiper of an operating medium store. The operating medium store comprises a plurality of absorbent disks 187 which are stacked on one another and which are saturated with an operating medium for the roller element bearing 181, e.g. with a lubricant.

In the operation of the vacuum pump 111, the operating medium is transferred by capillary action from the operating medium store via the wiper to the rotating splash nut 185 and is conveyed as a consequence of the centrifugal force along the splash nut 185 in the direction of the outer diameter of the splash nut 185, which becomes larger, to the roller element bearing 181, where it e.g. satisfies a lubricating function. The roller element bearing 181 and the operating medium store are encompassed in the vacuum pump by a tub-shaped insert 189 and by a bearing cap 145.

The permanent magnet bearing 183 comprises a bearing half 193 at the rotor side and a bearing half 193 at the stator side which each comprise a ring stack of a plurality of permanent magnetic rings 195, 197 respectively stacked on one another in the axial direction. The ring magnets 195, 197 are disposed opposite one another while forming a radial bearing gap 199, with the ring magnets 195 at the rotor side being arranged radially outwardly and the ring magnets 197 at the stator side being arranged radially inwardly. The magnetic field present in the bearing gap 199 effects magnetic repulsion forces between the ring magnets 195, 197 which effect a radial support of the rotor shaft 153. The ring magnets 195 at the rotor side are carried by a carrier section 201 of the rotor shaft 153, with the carrier section 201 surrounding the ring magnets 195 at the radially outer side. The ring magnets 197 at the stator side are carried by a carrier section 203 at the stator side which extends through the ring magnets 197 and is suspended at radial struts 205 of the housing 119. The ring magnets 195 at the rotor side are fixed in parallel with the axis of rotation 151 by a cover element 207 coupled to the carrier section 203. The ring magnets 197 at the stator side are fixed in parallel with the axis of rotation 151 in the one direction by a fastening ring 209 connected to the carrier section 203 and by a fastening ring 211 connected to the carrier section 203. A plate spring 213 can additionally be provided between the fastening ring 211 and the ring magnets 197.

An emergency bearing or safety bearing 215 is provided within the magnetic bearing; it idles in the normal operation of the vacuum pump 111 without contact and only moves into engagement on an excessive radial deflection of the rotor 149 relative to the stator to form a radial abutment for the rotor 149 since a collision of the structures at the rotor side with the structures at the stator side is prevented. The safety bearing 215 is configured as a non-lubricated roller element bearing and forms a radial gap with the rotor 149 and/or with the stator, said gap having the effect that the safety bearing 215 is out of engagement in normal pump operation. The radial deflection at which the safety bearing 215 comes into engagement is dimensioned sufficiently large that the safety bearing 215 does not move into engagement in the normal operation of the vacuum pump and is simultaneously small enough that a collision of the structures at the rotor side with the structures at the stator side is avoided under all circumstances.

The vacuum pump 111 comprises the electric motor 125 for a rotating driving of the rotor 149. The armature of the electric motor 125 is formed by the rotor 149 whose rotor shaft 153 extends through the motor stator 217. A permanent magnet arrangement can be arranged at the radially outer side or in an embedded manner on the section of the rotor shaft 153 extending through the motor stator 217. An intermediate space 219 which comprises a radial motor gap via which the motor stator 217 and the permanent magnet arrangement 128 can have a magnetic influence for transferring the drive torque is arranged between the motor stator 217 and the section of the rotor 149 extending through the motor stator 217.

The motor stator 217 is fixed in the housing within the motor space 137 provided for the electric motor 125. A barrier gas that is also called a purge gas and which can be air or nitrogen, for example, can reach the motor space 137 via the barrier gas connector 135. The electric motor 125 can be protected from process gas, e.g. from corrosively active portions of the process gas, via the barrier gas. The motor space 137 can also be evacuated via the pump outlet 117, i.e. the vacuum pressure effected by the backing pump connected to the pump outlet 117 is at least approximately present in the motor space 137.

In addition, a so-called labyrinth seal 223 that is known per se can be provided between the rotor hub 161 and a wall 221 bounding the motor space 137, in particular to achieve a better sealing of the motor space 217 with respect to the Holweck pump stages disposed radially outside.

As has already been initially explained, a NEG coating over as large an area as possible of the surfaces of the device in contact with the vacuum is desirable to obtain a maximum—active and passive—effect of the coating. A (partial) coating of components (e.g. of the recipient) arranged upstream of the pump 111 is also conceivable. Good results can, however, often already be reached if only individual components or regions of the pump 111 are coated.

The interior of the housing 119 can in particular be fully or partly coated. A coating of the housing 119 in the region of the inlet 115 and/or of the elements arranged there (e.g. struts 205, carrier section 203) is particularly effective. The components of the turbomolecular pump stages (in particular the rotor disks 155, the stator disks 157, and the spacer rings 159) can also be fully or partly coated. Particularly a coating of the pump stages at the inlet side (for example, the first two pump stages) achieves considerable effects.

A NEG coating in the region of the Holweck pump stages, in particular of the pump-active surfaces, additionally increases the efficiency of the pump 111.

The same considerations as those presented above in connection with the pump 111 generally apply to other vacuum devices, e.g. sensors, measuring devices, and valves.

The function of a magnetron sputtering head 10 shown in FIG. 6 and in particular suitable for coating tubular components can be understood with reference to the sectional drawing of FIG. 7. The head 10 comprises a target 12 composed of pre-alloyed NEG material having a substantially planar target surface 11. A ring magnet 14 (south pole S at the top, north pole N at the bottom) and a cylindrical magnet 16 (top N, bottom S) are located at a rear side 1 a of the target 12—embedded in a base 13. The magnetic field lines B generated by the magnet arrangement 14, 16 extend from the north pole N of the cylindrical magnet 16 to, the south pole (S) of the ring magnet 14, and vice versa.

The target 12 serves as a cathode (−) and a ground shield 18 that surrounds the base 13 and the target 12 serves as an anode (+) of the sputtering arrangement. The ground shield 18 is connected to the housing of the coating plant via a pipe 20 (lance) and a flange 22 and is located on ground potential. The ground shield 18 and the target 20 are non-conductively insulated from one another, for example by an insulation 24.

High voltage (HV) in the range 300 V to 1200 V is applied between both electrodes (shield 18 on the one hand, target 12, base 13 on the other hand). A strong electric field E is thereby generated between the target 12 and the ground shield 18. Electrons generated by cosmic radiation and—after ignition of the plasma (see below)—secondary electrons from the cathode (shield 18) strive toward the anode (target 12) and are forced between the cathode and the anode by the effect of the E field and of the B field on spiral paths (vector product E×B).

A vacuum chamber that has been pumped down to a residual gas pressure of 10⁻⁶ mbar is flooded with a noble gas up to a pressure of 10⁻² mbar with an activated HV. At this pressure, an argon-ion plasma ignites at a given high voltage (1200 V) due to the free electrons present, which is also described by Paschen's law. The positive argon ions are accelerated by the electrical field away from the shield 18 and thus toward the target 12. They impact the target 12 and atomize the target material. The target material is subsequently deposited everywhere—also on the substrate to be coated—so that a thin film arises there.

After a plasma ignition has taken place, the noble gas pressure is reduced into a range of 10⁻³ mbar. The thermalization of the evaporated target atoms that is thereby smaller has a higher sputter rate and a higher quality of the film (adhesion, density, purity) as a consequence. It was able to be shown that the composition of the coating (deposited target material) agrees 100% with the composition of the target 12.

Two copper pipes 26 through which cooling water flows to cool the base 13 and thus ultimately also the target 12 lead through the pipe 20 (lance). The cooling of the target material that is permanently heated by the plasma discharge at a power density of approximately 5 W/cm² namely takes place via the base 13 at the rear target side 11a. The base 13 can be a copper block. It serves both for holding the target and for an effective cooling. It can have a plurality of cooling passages to be able to provide a cooling effect that is as uniform as possible.

The copper pipes 26 are electrically conductively connected to the target 12 via the base 13 acting as a heat sink. The negative high voltage that is applied to the end of the copper pipes 26 is thus also applied to the target 12.

The dimensions of the sputtering head 10 can be selected in dependence on the substrate to be coated, e.g. the outer diameter of the head 10 is adapted to the inner diameter of a pipe to be coated from the inside. This has the consequence of an optimization of the sputter rate, of the adhesion, of the material quality, and of the process time.

It is understood that the head 10 and/or the target 12 can also have a non-circular geometry. Ellipsoid, quadratic, rectangular, or polygonal geometries are also conceivable.

In principle, all kinds of substrates (metals, semiconductors, and non-conductors) can be coated with NEG using this technique.

To increase the adhesion of the coating on the substrate, last water residues/water films (typically film thicknesses of 10-100 angstrom) are removed by ion bombardment prior to the coating with NEG. This method is considerably more gentle and time-saving than the thermal heating of the substrate at temperatures around 300° C.

To coat an extensive substrate 40, provision can be made to travel the substrate 40 (here a pipe by way of example) and the head 10 relative to one another (see FIG. 8). This can take place by traveling the sputtering head 10 (see arrow A). The substrate 40 is here arranged in a coating chamber. The pipe 20 of the head 10 is led through a vacuum leadthrough 44 in a wall 42 of the coating chamber. A movement of the pipe 20 results in a movement of the target 12 relative to the substrate 40. Alternatively, the substrate 40 can be moved relative to a head 10 arranged as stationary within the coating chamber by means of a rail transport system (see arrow B). This method has the advantage that no pushing leadthroughs 44 are required in the chamber wall 42. It is understood that the head 10 can also be arranged as travelable in the chamber. Both the substrate 40 and the head 10 can then be moved.

It is also possible for an acceleration of the coating process to use two sputtering heads 10 (FIG. 8, top) that project into the respective pipe ends instead of only one sputtering head 10 (FIG. 8, bottom). The coating time can be halved by the simultaneous operation of both sputtering heads.

The above statements apply in an analogous form to the coating of planar substrates by means of a method that provides a relative movement of the substrate and of the target.

1-24. (canceled)

25. A vacuum device, having at least one component that has a section that is in contact with a vacuum in an operation of the vacuum device and that is at least sectionally coated with a film absorbing gas particles.

26. The vacuum device in accordance with claim 25,
wherein the film comprises titanium, zirconium and/or vanadium; and/or
wherein the film comprises a mixture of titanium, zirconium, and vanadium; and/or
wherein the component is a component that is static in operation of the device; and/or
wherein the component is a component that can be driven to make a movement in operation of the device; and/or
wherein the component is a component generating a pump effect.

27. The vacuum device in accordance with claim 25,
wherein the device is a vacuum pump in which at least one of an inlet region and components arranged in the inlet region is at least sectionally coated with the film.

28. A method of NEG coating components of a vacuum plant and/or components of vacuum devices, by a sputtering process,
in which method at least one non-wire shaped target is used.

29. A method of NEG coating components of a vacuum plant and/or components of vacuum devices by a sputtering process,
in which method the target and the component are moved relative to one another during the sputtering process.

30. The method in accordance with claim 28,
wherein a target is used that has an at least sectionally planar target surface.

31. The method in accordance with claim 29,
wherein a target is used that has an at least sectionally planar target surface.

32. The method in accordance with claim 28,
wherein the coated component is a tubular component; or wherein the coated component is a tubular component and the target is oriented relative to the tubular component during the sputtering process such that the outer margin of the target is disposed in a plane extending perpendicular to the longitudinal axis of the tubular component.

33. The method in accordance with claim 29,
wherein the coated component is a tubular component; or wherein the coated component is a tubular component and the target is oriented relative to the tubular component during the sputtering process such that the outer margin of the target is disposed in a plane extending perpendicular to the longitudinal axis of the tubular component.

34. The method in accordance with claim 28,
wherein a planar target or a target having at least one planar surface is used; and/or
wherein a sectionally planar or plate-like component is coated by means of a planar target or by means of a target having at least one planar surface.

35. The method in accordance with claim 29,
wherein a planar target or a target having at least one planar surface is used; and/or
wherein a sectionally planar or plate-like component is coated by means of a planar target or by means of a target having at least one planar surface.

36. The method in accordance with claim 28,
wherein the target comprises an alloy or consists of an alloy that contains titanium, zirconium, and vanadium; and/or
wherein a NEG coating is generated that can be activated by heating and that is able, in an activated state, to bind residual gas atoms at its surface.

37. The method in accordance with claim 29,
wherein the target comprises an alloy or consists of an alloy that contains titanium, zirconium, and vanadium; and/or
wherein a NEG coating is generated that can be activated by heating and that is able, in an activated state, to bind residual gas atoms at its surface.

38. The method in accordance with claim 28,
wherein a NEG coating is produced that is able, after a repeat activation, to desorb residual gas atoms previously bound to its surface and/or to allow them to migrate into the interior of the NEG coating; and/or
wherein a NEG coating is produced that has a degassing rate in a non-activated state that amounts to between 10⁻¹⁴ and 10⁻¹⁵ mbar*l*s⁻¹*cm².

39. The method in accordance with claim 29,
wherein a NEG coating is produced that is able, after a repeat activation, to desorb residual gas atoms previously bound to its surface and/or to allow them to migrate into the interior of the NEG coating; and/or
wherein a NEG coating is produced that has a degassing rate in a non-activated state that amounts to between 10⁻¹⁴ and 10⁻¹⁵ mbar*l*s⁻¹*cm².

40. The method in accordance with claim 28,
wherein a NEG coating is produced by means of which a pressure of less than 5×10⁻¹¹ mbar can be reached in a closed space without an additional pump effect; and/or
wherein the sputtering process is carried out such that foreign atoms present on a surface of the respective component to be coated are removed by the sputtering atoms.

41. The method in accordance with claim 29,
wherein a NEG coating is produced by means of which a pressure of less than 5×10⁻¹¹ mbar can be reached in a closed space without an additional pump effect; and/or
wherein the sputtering process is carried out such that foreign atoms present on a surface of the respective component to be coated are removed by the sputtering atoms.

42. A method of operating a vacuum device, that comprises at least one component that is provided with a NEG coating, in which method the component provided with the NEG coating is activated by heating before the use of the vacuum device in accordance with its intended purpose.

43. The method in accordance with claim 42,
wherein the component is heated to at least substantially 200° C.

44. The method in accordance with claim 42,
wherein the component is held at a temperature that at least substantially amounts to 200° C. over a time period of at least substantially 24 hours.
